(19) United States
(12) Patent Application Publication
(10) Pub. No.: US 2015/0145586 A1
(43) Pub. Date: May 28, 2015

(54) GATE DRIVING DEVICE AND INVERTER HAVING THE SAME

(71) Applicant: SAMSUNG ELECTRO-MECHANICS CO., LTD., Suwon-Si (KR)

(72) Inventor: Won Jin CHO, Suwon-Si (KR)

(73) Assignee: SAMSUNG ELECTRO-MECHANICS CO., LTD., Suwon-Si (KR)

(21) Appl. No.: 14/262,333

(22) Filed: Apr. 25, 2014

(30) Foreign Application Priority Data
Nov. 26, 2013 (KR) 10-2013-0144466

(51) Int. Cl. H03K 17/16

(52) U.S. Cl. CPC H03K 17/16; H03K 2217/0063; H03K 2217/0072; H03K 2217/0081
USPC 327/379

(57) ABSTRACT

A gate driving device may include an inverter arm including a high-side switch and a low-side switch, a gate driving unit including a first gate driver that receives an instruction signal to command switching controlling of the inverter arm to output a switching control signal for the high-side switch and the low-side switch, and a second gate driver that receives the switching control signal for the high-side switch to be output to the high-side switch, and a balancing unit maintaining balance in voltage between the first gate driver and the second gate driver, according to the switching of the inverter arm based on the switching control signal for the high-side switch.

### CROSS-REFERENCE TO RELATED APPLICATION

This application claims the benefit of Korean Patent Application No. 10-2013-0144466 filed on Nov. 26, 2013, with the Korean Intellectual Property Office, the disclosure of which is incorporated herein by reference.

### BACKGROUND

The present disclosure relates to a gate driving device driven at high voltage and an inverter having the same.

Generally, an inverter is an element that receives direct current power to output alternating current power and is capable of controlling the amplitude of a voltage, a frequency and the like of output alternating current power, thereby outputting alternating current power or driving a motor or the like.

Such an inverter may be widely used in domestic, commercial and industrial applications.

A driving device may be employed to drive such an inverter, which drives the inverter byway of turning switches of inverter arms on and off switches of inverter arms to supply alternating current power.

For industrial applications of the inverter, high voltage alternating current power may be required depending on industrial requirements.

A typical inverter may employ gate driving integrated circuits, each of which turns a high-side switch and a low-side switch of an inverter arm on and off, respectively. With this configuration, since high voltage is applied to the high-side switch, the gate driving integrated circuit turning the high-side switch on and off should have withstanding voltage characteristics against high voltage level applied to the high-side switch.

In an inverter for industrial use, a voltage of approximately 1200V may be applied to the high-side switch, and thus the gate driving integrated circuit controlling the high-side switch needs to have withstand voltage characteristics of 1200V or higher. However, such a gate driving integrated circuit having high withstand voltage characteristics is relatively expensive to manufacture.

### SUMMARY

An exemplary embodiment in the present disclosure may provide a gate driving device stably operable at high voltage, and an inverter having the same.

An embodiment in the present disclosure may also provide a gate driving device capable of preventing voltages above a withstand voltage level from being applied in a transient state, and an inverter having the same.

According to an embodiment in the present disclosure, a gate driving device may include: an inverter arm including a high-side switch and a low-side switch; a gate driving unit including a first gate driver that receives an instruction signal to command switching controlling of the inverter arm to output a switching control signal for the high-side switch and the low-side switch, and a second gate driver that receives the switching control signal for the high-side switch to be output to the high-side switch; and a balancing unit maintaining balance in voltage between the first gate driver and the second gate driver according to the switching of the inverter arm based on the switching control signal for the high-side switch.

The balancing unit may include a plurality of balancers, each of the plurality of balancers being connected to the respective first and second gate drivers and equally dividing voltage applied to the first and second gate drivers.

Each of the balancers may include a resistor connected to the respective first and second gate drivers in parallel.

Each of the balancers may include a capacitor connected to the resistor in parallel.

The balancing unit may maintain a state of voltage divided between the plurality of gate drivers when the switching control signal for the high-side switch, output from the first gate driver or the second gate driver, is changed from a high level to a low level.

The gate driving device may further include a single voltage source supplying the gate driving unit with a supply voltage.

The gate driving device may further include a voltage supply unit transmitting the supply voltage to the first gate drive or the second gate driver.

The voltage supply unit may include a plurality of diodes connected to one another in series.

The voltage supply unit may include a plurality of diodes connected to one another in parallel.

According to an embodiment in the present disclosure, an inverter may include: an inverter unit including an inverter arm having a high-side switch and a low-side switch connected to each other in series between an input terminal to which input voltage of a predetermined voltage level is input and a ground, and switching the input voltage to output alternating current power; a gate driving unit having a plurality of gate drivers disposed between an input terminal at which an instruction signal to command switching controlling by the inverter unit is received and an output terminal from which a control signal to control switching of the inverter unit is output, and controlling switching of the high-side switch or the low-side switch; and a balancing unit dividing voltage applied to the gate drivers between the gate drivers according to the switching of the high-side switch, and maintaining a state of the divided voltage between the gate drivers.

The balancing unit may include a plurality of balancers, each of the plurality of balancers being connected to the respective gate drivers so as to equally divide voltage applied to the plurality of gate drivers therebetween.

Each of the balancers may include a resistor connected to the respective gate drivers in parallel.

Each of the balancers may include a capacitor connected to the resistor in parallel.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a block diagram of a gate driving device according to an exemplary embodiment of the present disclosure;

FIG. 2 is a diagram of a gate driving device according to another exemplary embodiment of the present disclosure;

FIG. 3 is a diagram for illustrating an example of the balancing unit shown in FIG. 2;

FIG. 4 is a diagram for illustrating another example of the balancing unit shown in FIG. 2;

FIG. 5 is a diagram for illustrating an example of the voltage supply unit shown in FIG. 2;

FIG. 6 is a diagram for illustrating another example of the voltage supply unit shown in FIG. 2; and

FIG. 7 is a diagram for illustrating an inverter according to an exemplary embodiment of the present disclosure.

### DETAILED DESCRIPTION

Hereinafter, embodiments of the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. Throughout the drawings, the same or like reference numerals will be used to designate the same or like elements.

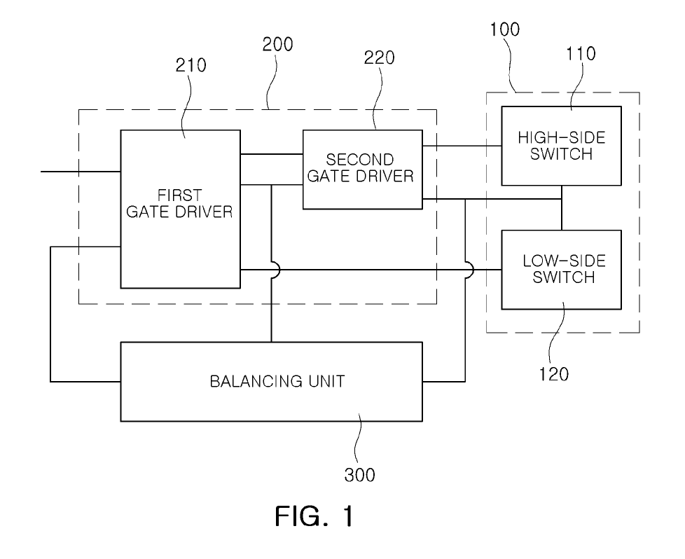

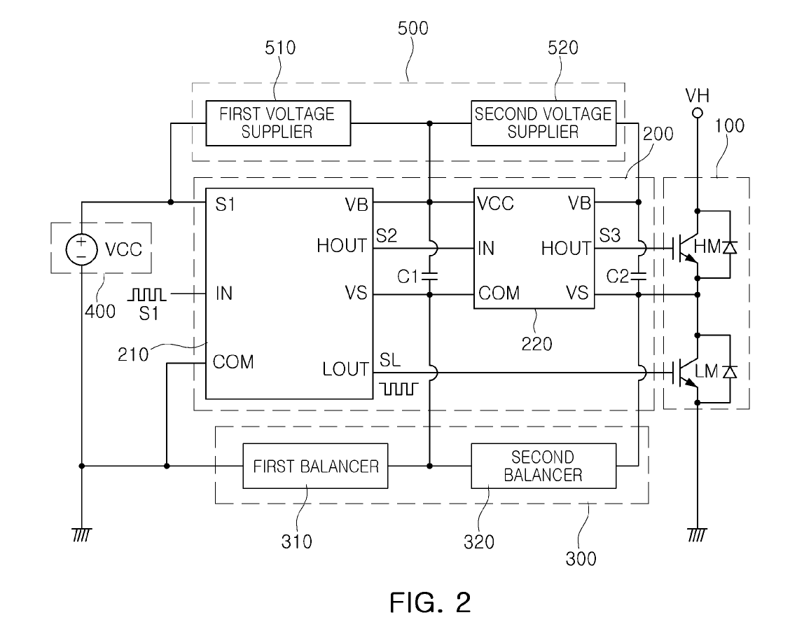

FIG. 1 is a block diagram of a gate driving device according to an exemplary embodiment of the present disclosure, and FIG. 2 is a diagram of a gate driving device according to another exemplary embodiment of the present disclosure.

Referring to FIGS. 1 and 2, the gate driving device may include an inverter arm 100, a gate driving unit 200 and a balancing unit 300.

The inverter arm 100 may switch an input voltage VH so that an inverter unit (not shown), to which the inverter arm 100 is connected, outputs alternating current power. The inverter unit (not shown) may include the inverter arm including a high-side switch HM and a low-side switch LM connected in series between an input terminal at which an input voltage of a predetermined level is received and a ground and may switch the input voltage to output alternating current power.

Further, the inverter arm 100 may include a high-side switch (HM) 110 and a low-side switch (LM) 120.

To the gate terminals of the high-side switch (HM) 110 and the low-side switch (LM) 120, control signals S3 and SL from the gate driving unit 200 are input so as to control switching-on and switching-off.

The gate driving unit 200 may be disposed between an instruction signal input terminal that receives an instruction signal S1 to command switching controlling over the inverter arm 100 and a control signal output terminal that outputs control signals S3 and SL to control switching of the inverter arm 100.

In addition, the gate driving unit 200 may include a first gate driver 210 and a second gate driver 220.

The first gate driver 210 may receive an instruction signal S1 to command switching controlling over the inverter arm 100 so as to output switching control signals S2 and SL for the high-side switch 110 and the low-side switch 120.

The second gate driver 220 may be connected to the first gate driver 210 in series and may receive the switching control signal S2 for the high-side switch 110 output from the first gate driver 210 so as to output a signal S3 to the high-side switch 110.

The balancing unit 300 may maintain balance in voltage between the first gate driver 210 and the second gate driver 220 according to the switching of the inverter arm 100 based on the switching control signal for the high-side switch 110.

Specifically, input power of the level corresponding to the input voltage VH may be input to the gate driving unit 200, according to the switching-on and switching-off of the high-side switch (HM) 110. The balancing unit 300 may divide the voltage level of the applied input power so that divided input voltage is applied to the first gate driver 210 and the second gate driver 220.

That is, the balancing unit 300 may divide the voltage applied to the gate driving unit between the first gate driver 210 and the second gate driver 220, according to the switching of the inverter arm 100.

In exemplary embodiment, the balancing unit 300 may include a plurality of balancers 310 and 320. The plurality of balancers 310 and 320 may be connected to the plurality of gate driver 210 and 220, respectively, so as to equally divide the voltage applied to the plurality of gate drivers 210 and 220.

Referring to FIG. 2, the balancing unit 300 may include a first balancer 310 and a second balancer 320. The first balancer 310 may be connected to the first gate driver 210 in parallel. The second balancer 320 may be connected to the second gate driver 220 in parallel.

With this configuration, the first balancer 310 and the second balancer 320 may equally divide the voltage level of the power to be applied to the first gate driver 210 and the second gate driver 220, according to the switching-on and switching-off of the high-side switch (HM) 110.

For example, if input voltage VH having the voltage level of 1200 V or higher is input, the voltage level applied to the gate driving unit 200 may be equally divided between the first gate driver 210 and the second gate driver 220, according to the switching-on and switching-off of the high-side switch (HM) 110. In this instance, a gate driver having withstand voltage of 600 V may be used as the first gate driver 210 and the second gate driver 220.

Further, the gate driving device may include a single voltage source 400 supplying supply voltage to the gate driving unit 200.

In order to apply supply voltage Vcc from the single voltage source 400 to the plurality of gate drivers 210 and 220, the gate driving unit 200 may further include a voltage supply unit 500.

The voltage supply unit 500 may include a plurality of voltage suppliers 510 and 520, which may supply the supply voltage Vcc to terminals of the gate driving units 210 and 220.

According to an exemplary embodiment of the present disclosure, when an ON signal is applied to the low-side switch (LM) 120 while an OFF signal is applied to the high-side switch (HM) 110, a first capacitor C1 and a second capacitor C2 are charged with Vcc by the single voltage source 400 and the voltage supply unit 500.

Then, when an OFF signal is applied to the low-side switch (LM) 120 while an ON signal is applied to the high side switch (HM) 110, input power having the voltage level corresponding to input voltage VH may be applied to the gate driving unit 200.

The applied voltage may be applied to the VS terminal of the second gate driver 220. Further, the voltage at the VB terminal of the second gate driver 220 may be determined by the voltage applied to the VS terminal and the second capacitor C2.

For example, the voltage at the VB terminal of the second gate driver 220 may be the sum of the voltage applied to the VS terminal of the second gate driver 220 and the voltage charged in the second capacitor C2.

When the applied voltage is equally divided by virtue of the first balancer 310 and the second balancer 320, the divided voltage may be applied to the VS terminal of the first gate driver 210.

Further, the voltage at the VB terminal of the first gate driver 210 may be determined by the voltage applied to the VS terminal of the first gate driver 210 and the first capacitor C1. For example, the voltage at the VB terminal of the first gate driver 210 may be the sum of the voltage applied to the VS terminal of the first gate driver 210 and the voltage charged in the first capacitor C1.

Accordingly, the range of the voltage of the control signal S3 for driving the high-side switch (HM) 110 at the output terminal HOUT may be determined by the voltage applied to the VS terminal of the first gate driver and the voltage applied to the Vcc terminal of the first gate driver.

That is, according to an exemplary embodiment of the present disclosure, the range of the voltage of the second gate driver 220 at the signal output terminal HOUT may be between the voltage level (e.g., VH) applied to the VS terminal of the second gate driver 220 and the voltage level (e.g., VH+Vcc) applied to the VB terminal of the second gate driver 220.

Further, the range of the voltage applied to the output terminal HOUT of the first gate driver 210 may be between the voltage level (e.g., 0.5*VH) applied to the VS terminal of the first gate driver 210 and the voltage level (e.g., 0.5*VH+Vcc) applied to the VB terminal of the second gate driver 220.

Further, the range of the voltage applied to the input terminal IN of the first gate driver 210 may be between the voltage level (e.g., 0 V) applied to the COM terminal of the first gate driver 210 and the voltage level (e.g., Vcc) applied to the Vcc terminal of the first gate driver 210.

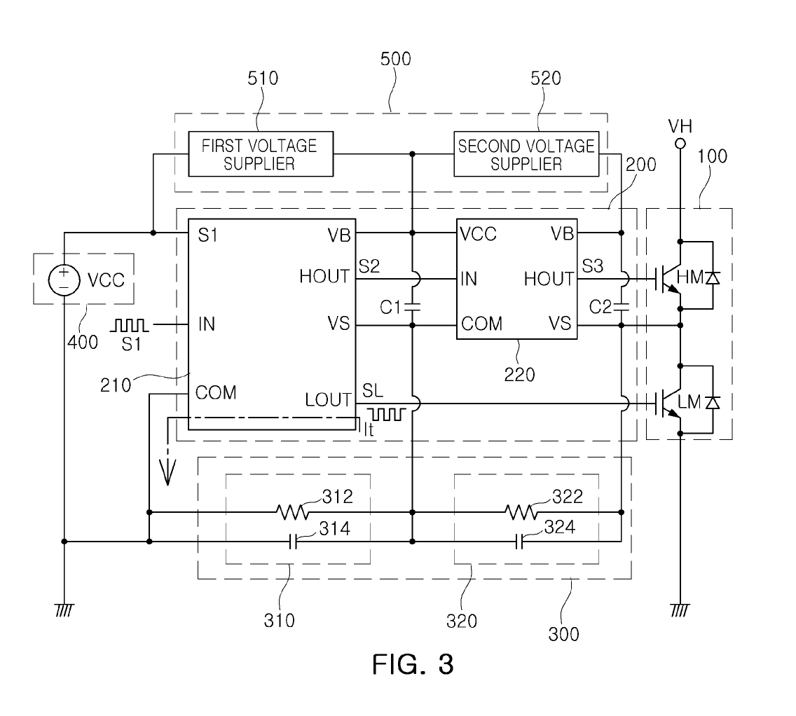

FIG. 3 is a diagram for illustrating an example of the balancing unit shown in FIG. 2.

Referring to FIG. 3, the balancing unit may include a first balancer 310 for a first gate driver 210, and a second balancer 320 for a second gate driver 220.

In the gate driver device shown in FIG. 3, other elements than the balancing unit 300 are identical to those described above and, therefore, detailed descriptions on the other elements will be omitted.

The first balancer 310 may include a first resistor 312a and a first capacitor 314. The first resistor 312 may be connected to the first gate driver 210 in parallel. Further, the first capacitor 314 may be connected to the first resistor 312 in parallel.

The second balancer 320 may include a second resistor 322 and a second capacitor 324. The second resistor 322 may be connected to the second gate driver 220 in parallel. Further, the second capacitor 324 may be connected to the second resistor 322 in parallel.

Referring to FIG. 3, if the resistance of the first resistor 312 and the resistance of the second resistor 322 are of the same value, the voltage may be equally divided between the first gate driver 210 and the second gate driver 220.

The first capacitor 314 and the second capacitor 324 may prevent unbalance of the voltage between the first gate driver 210 and the second gate driver 220 in a transient state. Here, the transient state may refer to a period of time in which the output signal S2 or S3 from the first gate driver 210 or the second gate driver 220, respectively, is changed from a high level to a low level.

That is, the balancing unit 300 may maintain the state of the voltage divided between the plurality of gate drivers 210 and 220 when a signal output from at least one of the plurality of gate drivers 210 and 220 is changed from a high level to a low level.

Referring to FIG. 3, when a control signal S3 is changed from a high level to a low level, a temporary current path It may be formed between the VS terminal of the first gate driver 210 and the COM terminal of the first gate driver 210.

When the balancing unit is configured only with the first resistor 312 and the second resistor 322 without the first capacitor 314 and the second capacitor 324, unbalancing in voltage dividing may occur between the first gate driver 210 and the second gate driver 220 if the current path It shown in FIG. 3 is formed. Such unbalancing in voltage dividing may result in voltages above a withstand voltage level applied to the first gate driver 210 or to the second gate driver 220. When this happens, the first gate driver 210 or the second gate driver 220 may be broken due to the voltage above the withstand voltage.

The first capacitor 314 and the second capacitor 324 may maintain balance of the voltage between the first gate driver 210 and the second gate driver 220 even in a transient state.

According to the embodiment of the present invention, at the time of switching input voltage of approximately 1200 V, by virtue of the first gate driver 210 and the second gate driver 220, a gate driving circuit having withstand voltage characteristics lower than 1200 V may be used.

For example, instead of an expensive gate driving circuit having withstanding voltage of 1200 V, voltage applied to the gate driving unit 200 at the time of switching is divided between the plurality of gate drivers 210 and 220 so that the driving circuit is stably operable, thereby reducing manufacturing cost.

Further, according to exemplary embodiments of the present disclosure, the first and second capacitors 314 and 324 may prevent voltage above the withstand voltage from being applied to the first gate driver 210 or the second gate driver 220 in a transient state.

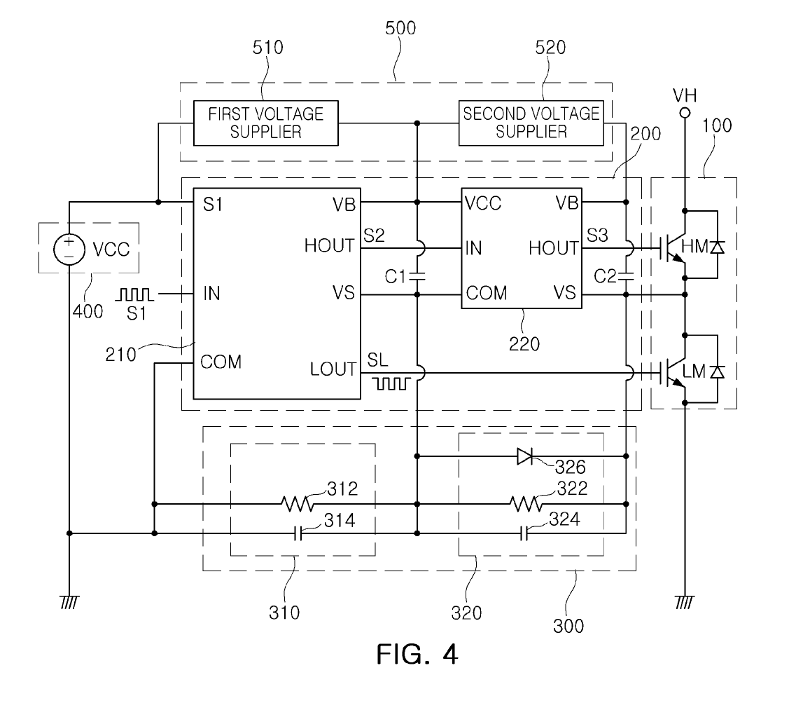

FIG. 4 is a diagram for illustrating another example of the balancing unit shown in FIG. 2.

Referring to FIG. 4, the first balancer 310 may include a first resistor 312 and a first capacitor 314. Further, the second balancer 320 may include a second resistor 322, a second capacitor 324 and a diode 326.

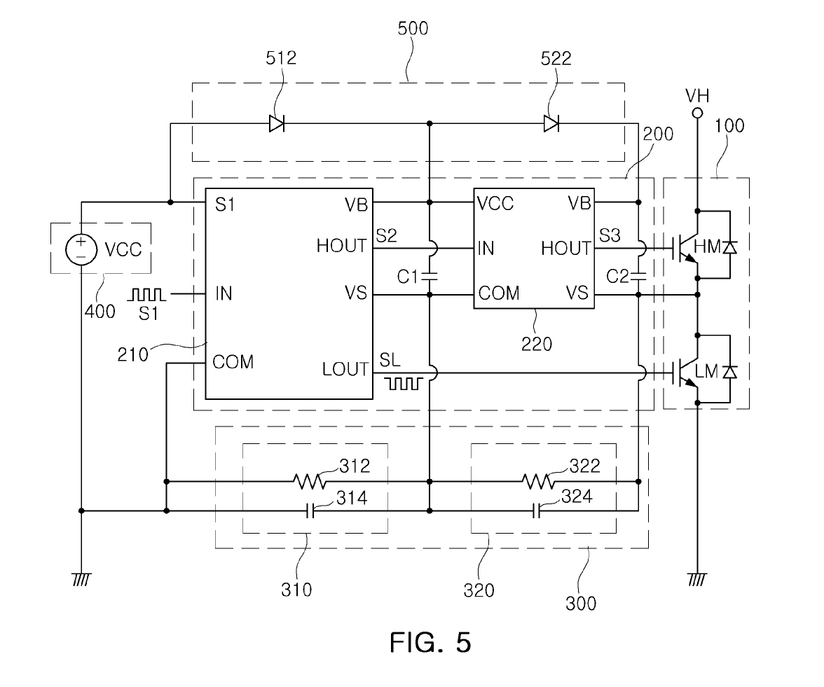

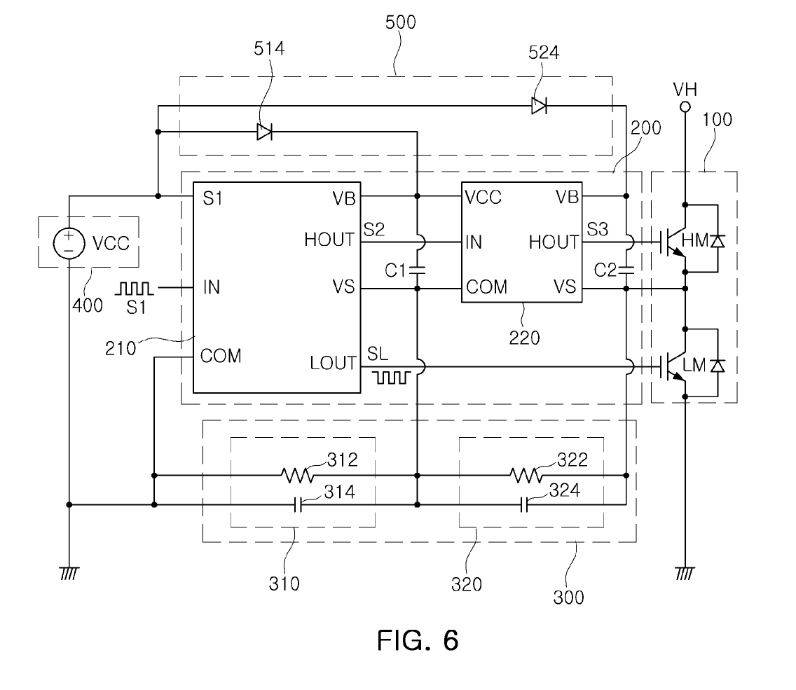

FIG. 5 is a diagram for illustrating an example of the voltage supply unit shown in FIG. 2, and FIG. 6 is a diagram for illustrating another example of the voltage supply unit shown in FIG. 2.

Referring to FIGS. 5 and 6, the voltage supply unit 500 may include a plurality of diodes.

Referring to FIG. 5, the voltage supply unit 500 may include a plurality of diodes 512 and 522 connected to each other in series.

Referring to FIG. 6, the voltage supply unit 500 may include a plurality of diodes 514 and 524 connected to each other in parallel.

In the gate driver devices shown in FIGS. 5 and 6, other elements than the voltage supply unit 500 are identical to those described above and, therefore, detailed descriptions on the other elements will be omitted.

The power supply unit 500 may deliver supply voltage Vcc from a single voltage source 400 to gate drivers 210 and 220. Further, the voltage supply unit 500 may form paths to charge capacitors C1 and C2 with the supply voltage Vcc from the single voltage source 400.

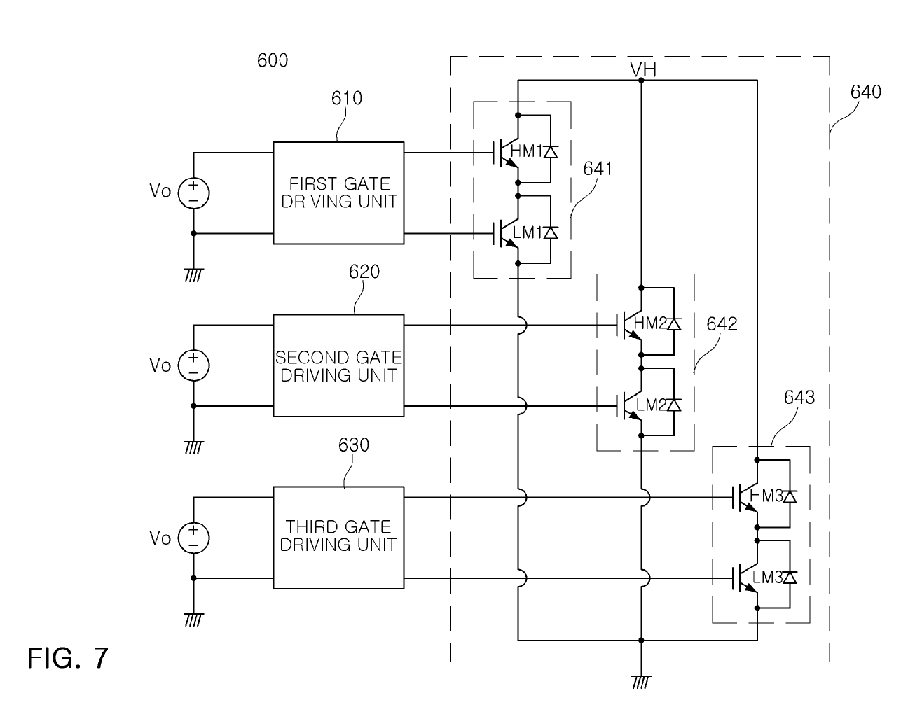

FIG. 7 is a diagram for illustrating an inverter according to an exemplary embodiment of the present disclosure.

As described above, the inverter unit 640 may include at least an inverter arm. The inverter unit 640 may include one inverter arm if an output alternating current power has a single phase and may include three inverter arms 641, 642 and 643 if output alternating current power has three phase as shown in FIG. 7.

In the latter case, the inverter 600 according to the exemplary embodiment of the present disclosure shown in FIG. 7 may include first to third gate driving units 610, 620 and 630 for controlling the switching-on and switching-off of high-side switches HM1, HM2 and HM3 or low-side switches LM1, LM2 and LM 3 of the three inverter arms 641, 642 and 643, respectively. In the inverter 600, each of the first to third gate driving units 610, 620 and 630 may include a balancing unit (not shown) that equally divides voltage between a plurality of gate drivers included therein.

The configurations of the first to third gate driver units 610, 620 and 630 and the balancing unit may be identical to those of the gate driving unit 200 and the balancing unit 300 shown in FIGS. 2 through 5, and thus redundant descriptions will not be made.

As set forth above, according to exemplary embodiments of the present disclosure, a gate driving device stably operable at high voltage, and an inverter having the same can be provided.

Further, a gate driving device capable of preventing voltages above a withstand voltage level from being applied in a transient state, and an inverter having the same can be provided.

While exemplary embodiments have been shown and described above, it will be apparent to those skilled in the art that modifications and variations could be made without departing from the spirit and scope of the present disclosure as defined by the appended claims.

What is claimed is:

1. A gate driving device, comprising:
an inverter arm including a high-side switch and a low-side switch;
a gate driving unit including a first gate driver that receives an instruction signal to command switching controlling of the inverter arm to output a switching control signal for the high-side switch and the low-side switch, and a second gate driver that receives the switching control signal for the high-side switch to be output to the high-side switch; and
a balancing unit configured to maintain balance in voltage between the first gate driver and the second gate driver, according to the switching of the inverter arm based on the switching control signal for the high-side switch.

2. The gate driving device of claim 1, wherein the balancing unit includes a plurality of balancers, each of the plurality of balancers being connected to the respective first and second gate drivers and equally dividing voltage applied to the first and second gate drivers.

3. The gate driving device of claim 2, wherein each of the balancers includes a resistor connected to the respective first and second gate drivers in parallel.

4. The gate driving device of claim 3, wherein each of the balancers includes a capacitor connected to the resistor in parallel.

5. The gate driving device of claim 1, wherein the balancing unit maintains a state of voltage divided between the plurality of gate drivers when the switching control signal for the high-side switch, output from the first gate driver or the second gate driver, is changed from a high level to a low level.

6. The gate driving device of claim 1, further comprising a single voltage source supplying the gate driving unit with a supply voltage.

7. The gate driving device of claim 6, further comprising a voltage supply unit transmitting the supply voltage to the first gate drive or the second gate driver.

8. The gate driving device of claim 7, wherein the voltage supply unit includes a plurality of diodes connected to one another in series.

9. The gate driving device of claim 7, wherein the voltage supply unit includes a plurality of diodes connected to one another in parallel.

10. An inverter comprising:
an inverter unit including an inverter arm having a high-side switch and a low-side switch connected to each other in series between an input terminal to which input voltage of a predetermined voltage level is input and a ground, and switch the input voltage to output alternating current power;
a gate driving unit including a plurality of gate drivers disposed between an input terminal at which an instruction signal to command switching controlling by the inverter unit is received and an output terminal from which a control signal to control switching of the inverter unit is output, and control switching of the high-side switch or the low-side switch; and
a balancing unit configured to divide voltage applied to the gate drivers between the gate drivers according to the switching of the high-side switch, and maintain a state of the divided voltage between the gate drivers.

11. The inverter of claim 10, wherein the balancing unit includes a plurality of balancers, each of the plurality of balancers being connected to the respective gate drivers so as to equally divide voltage applied to the plurality of gate drivers therebetween.

12. The inverter of claim 11, wherein each of the balancers includes a resistor connected to the respective gate drivers in parallel.

13. The inverter of claim 12, wherein each of the balancers includes a capacitor connected to the resistor in parallel.
